(19) United States
(12) Patent Application Publication
(10) Pub. No.: US 2015/0108668 A1
(43) Pub. Date: Apr. 23, 2015

(54) SUBLIMATION PURIFICATION APPARATUS AND METHOD

(71) Applicant: Rohm and Haas Electronic Materials Korea Ltd., Cheonan (KR)

(72) Inventors: Jeong-Su Baeck, Cheonan (KR); Jong-Won Jeong, Yongin (KR); Dae-Hoon Kim, Cheonan (KR); See-Yong Kim, Cheonan (KR); Young-Woong Nam, Cheonan (KR); Beom-Gyu Park, Cheonan (KR); Jung-Hwan Park, Cheonan (KR); Sung-Ho Park, Cheonan (KR)

(73) Assignee: Rohm and Haas Electronic Materials Korea Ltd., Cheonan (KR)

(21) Appl. No.: 14/399,405

(22) PCT Filed: May 20, 2013
(86) PCT No.: PCT/KR2013/004393

§ 371 Date: Nov. 6, 2014

(30) Foreign Application Priority Data
May 21, 2012 (KR) 10-2012-0053803

(51) Int. Cl. B01D 7/00; H01L 51/00

(52) U.S. Cl. CPC B01D 7/00; H01L 51/0025
USPC 260/1; 422/244

(57) ABSTRACT

The invention relates to a sublimation purification apparatus and a method for purifying a material for an organic light-emitting diode (OLED). Conventional sublimation purification apparatuses are batch type, where one sublimation purification process is performed by loading one source material into the processor chamber, and then unloading a purified material from the process chamber. These processes are manually performed, and thus it is not possible to continuously produce the purified material for the OLED. Therefore, it is difficult to increase a throughput and productivity. According to the invention, loading the source material and unloading the purified material are performed automatically, thus enabling a continuous process of purifying the source material for the OLED.

### FIELD OF THE INVENTION

The present invention relates to an apparatus and a method for purifying a material for an organic light-emitting diode (OLED) and, more particularly, to an apparatus and a method for sublimating and recrystallizing an organic material under a vacuum state.

### BACKGROUND OF THE INVENTION

Typically, materials used for an organic light-emitting diode (OLED) require purification. Purifying technology of the OLED materials is intended to extract only pure components required for electroluminescence from composite materials and to use the extracted components for thin film deposition. As the purifying technology of the OLED materials is improved, color purity and luminous efficiency are improved and the luminous lifetime of the OLED is prolonged. For the purpose of mass production of the OLED materials, the purifying technology for the OLED materials, which reduces the process time and improves purification efficiency, is essential.

A sublimation purification method of an organic material is disclosed in a thesis by H. J. Wagner. et al., Journal of Materials Science, 17, 2781, (1982). In this thesis, a glass tube with a length of approximately 1 meter is inserted into a copper tube for thermal conduction, and a source material to be purified to produce the OLED material are disposed within a region of one end of the glass tube. A heater surrounds the copper tube containing the source material, and an interior of the glass tube maintains a vacuum state. The heater heats the source material within the glass tube, and thereby the source material is sublimated. The glass tube is made to be a temperature gradient, and thereby the sublimated material is cooled and recrystallized at the other end of the glass tube. Thereby, recrystallized organic material is created within the region of the other end of the glass tube.

Typical purifiers are a batch type due to restrictions of the purification process. A source material that can be used once is loaded, and then the purified material is unloaded after the sublimation purification process. Thereby, the first process is completed. A sublimation purification apparatus and a sublimation purification method using the same are disclosed in Korean Laid-Open Publication No. 10-2010-0114342. However, the conventional sublimation purification apparatus and method as disclosed in such a document have a limitation in productivity and throughput, because the process is manually performed in turn.

### TECHNICAL PROBLEM

The present invention is related to solving the above problems in the conventional apparatus and method, and is intended to provide a sublimation purification apparatus and method in which loading and transferring of a source material and unloading of a purified material are automated to enable a continuous process, and each process can be advanced in parallel at the same time, thereby increasing the productivity of a process of purifying a material for an organic light-emitting diode (OLED) to enable mass production.

### SOLUTION TO THE PROBLEM

According to an aspect of the present invention, there is provided a sublimation purification apparatus, which comprises:
a first robot having an arm for loading a container containing a source material into a process chamber;
the process chamber for performing a sublimation purification process to obtain a purified material from the source material, wherein the container containing the source material and a collector collecting a purified material are located at predetermined locations within the process chamber; and
a second robot having an arm for unloading the collector containing the purified material from the process chamber.

The sublimation purification apparatus may further comprise a preheating chamber for a preheating process of the source material contained in the container, wherein the preheated source material is loaded into the process chamber by the first robot.

The sublimation purification apparatus may further comprise a cooling chamber for a cooling process of the purified material contained in the collector, wherein the purified material is loaded into the cooling chamber by the second robot.

According to another aspect of h present invention, there is provided a sublimation purification method, which comprises:
preheating a source material contained in a container in a preheating chamber;
loading the container containing the preheated source material into a process chamber by using an arm of a first robot and locating the container at a predetermined location;
performing a sublimation purification process to obtain purified material from the source material in the process chamber, wherein the purified material is collected in a collector located at a predetermined location;
unloading the collector containing the purified material from the process chamber by using an arm a of a second robot; and
initiating another preheating process in the preheating chamber contemporaneously with the sublimation purification process.

The sublimation purification method may further comprise loading the unloaded collector containing the purified material to a cooling chamber by the second robot for cooling process of the purified material, wherein the cooling process is performed in contemporaneous with another sublimation purification process in the process chamber.

### ADVANTAGEOUS EFFECTS OF THE INVENTION

According to the sublimation purification apparatus and method of the present invention, the loading of the source material and the unloading of the purified material are automated to enable a continuous process, and thus the time required for the purification process of the OLED materials can be reduced. Thereby, productivity is enhanced and production costs are reduced. Furthermore, a plurality of processes can be performed in parallel at the same time, and thus the productivity per process chamber can be remarkably improved, Thus, the throughput per unit area in an OLED production factory is increased. Furthermore, an overall continuous automation process prevents impurities from being added to the purified material, and thus purified OLED materials having a high purity are produced. Thereby, it is possible to improve a luminous efficiency and a lifetime of the OLED.

### DESCRIPTION OF THE DRAWINGS

FIGS. 1a and 1b show a sublimation purification apparatus according to a first embodiment of the present invention.

FIGS. 2a and 2b show a sublimation purification apparatus according to a second embodiment of the present invention.

FIGS. 3a and 3b show a sublimation purification apparatus according to a third embodiment of the present invention.

FIG. 4 shows a sublimation purification apparatus according o a fourth embodiment of the present invention.

### MODE OF THE INVENTION

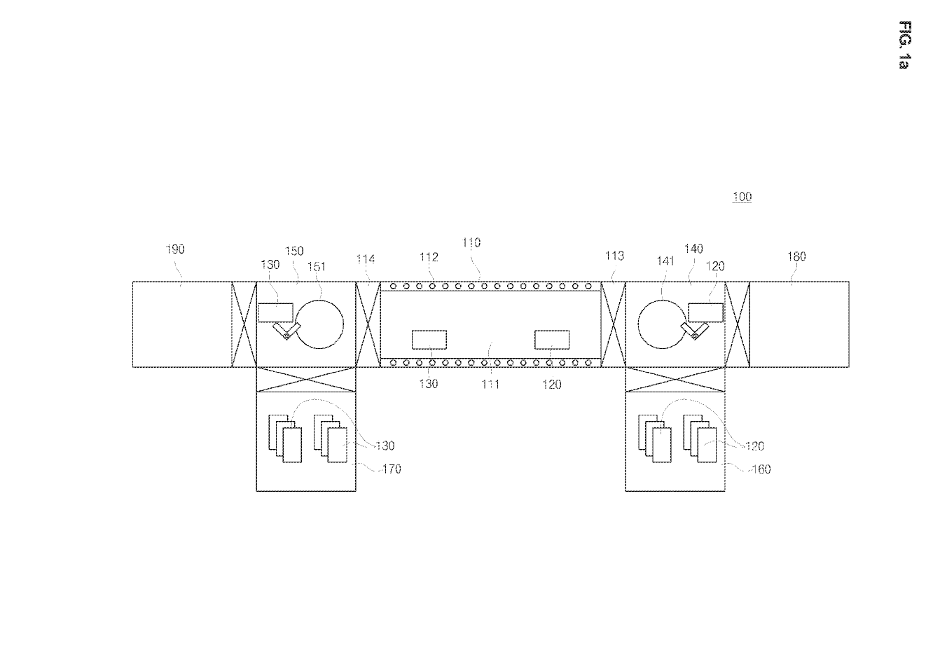

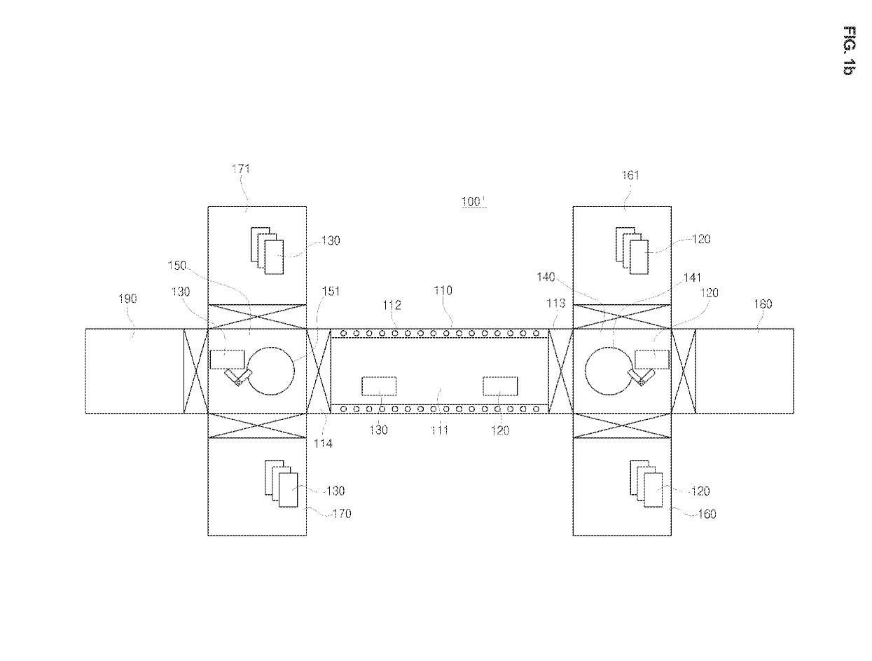

Referring to FIG. 1a, a sublimation purification apparatus 100 according to a first embodiment of the present invention is shown. The sublimation purification apparatus 100 of the present invention comprises a source material container 120 containing source materials for an OLED sublimation purification process, and a purified material collector 130 containing OLED materials purified in a purification process. Preferably, the source material container 120 may be boat-shaped, and the purified material collector 130 may be tube-shaped (i.e., a collecting tube).

Furthermore, the sublimation purification apparatus 100 of the present invention comprises a process chamber 110, in which the sublimation purification process for producing the OLED materials occurs. The process chamber 110 comprises an outer tube 111, a heater 112, and gates 113 and 114. The sublimation purification process is performed within the outer tube 111. The outer tube 111 is formed of a transparent material such as quartz or borosilicate glass, and fundamentally has a cylindrical shape. The outer tube 111 is surrounded with a heater 112. The outer tube 111 may be divided into a plurality of zones, and these zones may be adjusted to different temperatures by the heater 112. The gates 113 and 114 are disposed at opposite ends of the outer tube. The source material container 120 containing the source material is transferred into the outer tube 111 through the gate 113, and is loaded within the outer tube 111. When the purification process is completed, the empty source material container 120 is unloaded from the outer tube 111. Likewise, an empty purified material collector 130 is transferred into the outer tube 111 through the gate 114, and is loaded within the outer tube 111. When the sublimation purification process is completed, the purified material collector 130 containing the purified material is unloaded from the outer tube 111. An interior of the process chamber 110 maintains a vacuum state by a vacuum pump (not shown). Alternatively, the process chamber 110 may further comprise a trap or a valve (not shown).

The sublimation purification process within the process chamber 110 is as follows. The source material container 120 is transferred into the outer tube 111 through the gate 113 located at one end of the process chamber 110, and is loaded within the outer tube 111. When the source material is heated above a sublimation point of the OLED materials to be obtained in the purification process by the heater 112, the source material is sublimated and diffused within the outer tube 111. When the diffused source material is heated below the sublimation point of the OLED materials to be obtained in the purification process by the heater 112, the OLED materials are collected within the purified material collector 130. When the sublimation purification process is completed, the purified material collector 130 containing the purified materials is unloaded out of the process chamber 110 through the gate 114.

Referring to FIG. 1a again, the sublimation purification apparatus 100 of the present invention further comprises a transfer chamber 140 used for loading the source material container 120 into the process chamber 110, a source material storing means 160, and a preheating chamber 180. The transfer chamber 140 has a robot 141 for automatically transferring the source material container 120 between the process chamber 110 and the preheating chamber 180, within the transfer chamber 140. The robot 141 lifts and transfers the source material container 120 with an arm of the robot 141. Alternatively, the transfer chamber 140 of the present invention may further comprise a vacuum pump or a valve (not shown) connected to the transfer chamber 140.

In the first embodiment of the present invention, the transfer chamber 140 is connected to one end of the process chamber 110 via the gate 113. The source material storing means 160 is connected to the transfer chamber 140 via another gate of the transfer chamber 140, and the preheating chamber 180 is connected to the transfer chamber 140 via the other gate of the transfer chamber 140. The process chamber 110, the transfer chamber 140, the source material storing means 160, and the preheating chamber 180 may be separated from one another as necessary in the process.

The source material storing means 160 may be a chamber, in which one or more source material containers 120 containing the source materials are stored. Alternatively, the source material storing means 160 may further comprise a vacuum pump or a valve (not shown) connected to the source material storing means 160. When the gate between the transfer chamber 140 and the source material storing means 160 is open, the robot 141 transfers one of the plurality of source material containers 120 from the source material storing means 160 to the transfer chamber 140 using its arm.

When the gate between the transfer chamber 140 and the preheating chamber 180 is open, the robot 141 lifts and transfers the source material container 120 to the preheating chamber 180 with the arm of the robot 141. The gate between the transfer chamber 140 and the preheating chamber 180 is closed, and the preheating chamber 180 preheats the source material at a temperature lower than that at which the source material is heated in the process chamber 110. The robot 141 lifts and transfers the source material container 120 containing the preheated source materials from the preheating chamber 180 to the transfer chamber 140 with the arm of the robot 141. Mien the gate 113 of the process chamber 110 is open, the robot 141 loads the source material container 120 containing the source materials into the process chamber 110.

In order to implement a continuous process and to increase the process efficiency, while the above sublimation purification process is being performed, the robot 141 transfers the next source material container 120 containing the source materials from the source material storing means 160 into the transfer chamber 140, and then loads the source material container 120 into the preheating chamber 180. The preheating process of the next time is also performed in the preheating chamber 180 in the same way as described above. Since the present invention independently adopts the preheating process in the preheating chamber, a heating time in the process chamber 110 is reduced. Conventionally, both the preheating process and the sublimation purification process are performed in the process chamber. However, the sublimation purification apparatus of the present invention can reduce the time for which the preheating process is performed in the process chamber 110, by adopting the preheating chamber 180 which is independent from the process chamber 110, and thereby the process chamber 110 can be operated a greater number of times due to the reduced preheating time in the process chamber 110. Thus, the productivity of the sublimation purification process is increased on the whole.

Meanwhile, when the previous purification process is completed in the process chamber 110, the robot 141 lifts and transfers the empty source material container 120, which is left after the completion of the purification process, to the transfer chamber 140 with the arm of the robot 141, and then transfers the empty source material container 120 to the source material storing means 160 and stacks the empty source material container 120 in the source material storing means 160. At this time, the preheating process may be simultaneously performed in the preheating chamber 180.

Referring to FIG. 1a again, the sublimation purification apparatus 100 of the present invention further comprises a transfer chamber 150, a purified material storing means 170, and a cooling chamber 190, which are used for the automated process of unloading a purified material collector 130 containing purified materials from the process chamber 110. The transfer chamber 150 has a robot 151 for automatically transferring the purified material collector 130. The robot 151 transfers the purified material collector 130 with an arm of the robot 151. Alternatively, the transfer chamber 150 of the present invention may further comprise a vacuum pump or a valve (not shown) connected to the transfer chamber 150.

In the first embodiment of the present invention, the transfer chamber 150 is connected to the process chamber 110 through the gate 114 located at the other end of the process chamber 110. The purified material storing means 170 is connected to the transfer chamber 150 through another gate of the transfer chamber 150, and the cooling chamber 190 is connected to the transfer chamber 150 through the other gate of the transfer chamber 150. The process chamber 110, the transfer chamber 150, the purified material storing means 170, and the cooling chamber 190 may be separated from one another as necessary in the process.

The purified material storing means 170 may be a chamber in which one or more empty purified material collectors 130 containing the purified materials are stored. Alternatively, the purified material storing means 170 may further comprise a vacuum pump or a valve (not shown) connected to the purified material storing means 170. Before the purification process is performed in the process chamber 110, when the gate between the transfer chamber 150 and the purified material storing means 170 is open, the robot 151 lifts and transfers one of the plurality of empty purified material collectors 130 from the purified material storing means 170 to the transfer chamber 150 with the arm of the robot 151. When the gate 114 of the process chamber 110 is open, the robot 151 transfers the empty purified material collector 130 into the process chamber 110 with the arm of the robot 151.

When the purification process is completed in the process chamber 110, the gate 114 of the process chamber 110 is open again, the robot 151 unloads the purified material collector 130 containing the purified materials into the transfer chamber 150 with the arm of the robot 151. When the gate between the transfer chamber 150 and the cooling chamber 190 is open, the robot 151 transfers the purified material collector 130 into the cooling chamber 190 with the arm of the robot 151. A gate of the cooling chamber 190 is closed, and the cooling chamber 190 cools the purified material containing in the purified material collector 130. A temperature of the cooling chamber 190 is lower than a temperature at which the purified material collector 130 is heated in the process chamber, and is higher than the room temperature.

Furthermore, the robot 151 transfers the empty purified material collector 130 to be used for the next purification process from the purified material storing means 170 to the transfer chamber 150, and transfers the purified material collector 130 into the process chamber 110, and then the sublimation purification process is performed. The cooling process may be performed in the coding chamber 190 simultaneously with the sublimation purification process. Conventionally, both the sublimation purification process and the cooling process are performed in the process chamber. However, the sublimation purification apparatus of the present invention can reduce the time for which the cooling process is performed in the process chamber, by adopting the cooling chamber 190 which is independent from the process chamber 110, and thereby the process chamber 110 can be operated a greater number of times due to the reduced cooling time in the process chamber 110. Thus, the productivity of the sublimation purification process is increased on the whole.

In a conventional sublimation purification apparatus, it is assumed that it typically takes, in the process chamber, approximately one hour and thirty minutes to two hours and thirty minutes to perform the preheating process, approximately six to seven hours to perform the sublimation purification process, and approximately one hour and thirty minutes to two hours and thirty minutes to perform the cooling process. That is, it takes a total of approximately nine to twelve hours in the process chamber. However, according to the sublimation purification apparatus of the present invention, the processes are performed independently in the preheating chamber 180, the process chamber 110, and the cooling chamber 190, and thus it takes a total of about six to seven hours to perform the process in the process chamber 110. Thus, the time of the overall sublimation purification process is reduced.

The robot 151 lifts the purified material collector 130 containing the cooled purified materials, transfers the purified material collector 130 from the cooling chamber 190 to the transfer chamber 150, and transfers the purified material collectors 130 into the purified material storing means 170, with the arm of the robot 151. The sublimation purification process as described above is continuously repeated. As a result, one or more purified material collectors 130 containing the cooled purified materials are stored in the purified material storing means 170. Afterwards, the interior of the purified material storing means 170 goes to an atmospheric pressure, and then the purified materials contained in each purified material collector 130 are collected.

FIG. 1b shows a sublimation purification apparatus 100′ which partially modifies the apparatus according to the first embodiment shown in FIG. 1a. The sublimation purification apparatus 100′ of FIG. 1b further comprises an independent storing means 161 in which the empty source material containers 120 are stored after the purification process. In FIG. 1a, both the source material containers 120 containing the source materials before the purification process and the empty source material containers 120 after the purification process are stored in the source material storing means 160. However, in the sublimation purification apparatus 100′ shown in FIG. 1b, the source material containers 120 containing the source materials, which is stored in the source material storing means 160, is transferred into the preheating chamber 180 via the transfer chamber 140 by the robot 141, undergoes the preheating process, and then is transferred into the process chamber 110, whereas the empty source material container 120 after the purification process is unloaded from the process chamber 110 by the robot 141, is transferred via the transfer chamber 140, and is stored in the storing means 161 in which the empty source material containers 120 are stored.

Referring to FIG. 1b again, the sublimation purification apparatus 100′ of the present invention further comprises an independent storing means 171 in which the empty purified material collectors 130 to be used for the purification process are stored. In FIG. 1a, both the empty purified material collector 130 before the purification process and the purified material collector 130 containing the purified materials after the purification process are stored in the purified material storing means 170. However, in FIG. 1b, the purified material collector 130 containing the purified materials is unloaded from the process chamber 110 by the robot 151, is transferred to the cooling chamber 190 via the transfer chamber 150, undergoes the cooling process, and is transferred to and stored in the purified material storing means 170, whereas the empty purified material collector 130 to be used for the purification process is stored in the independent storing means 171 connected to the transfer chamber 150, and is transferred for the purification process from the independent storing means 171 into the process chamber 110 via the transfer chamber 150 by the robot 151.

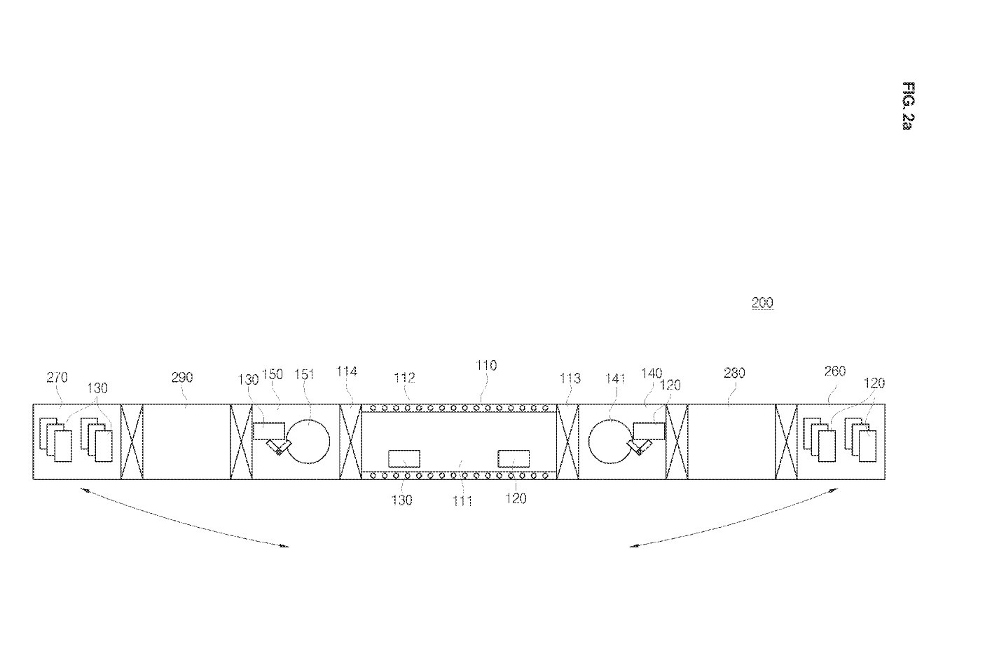

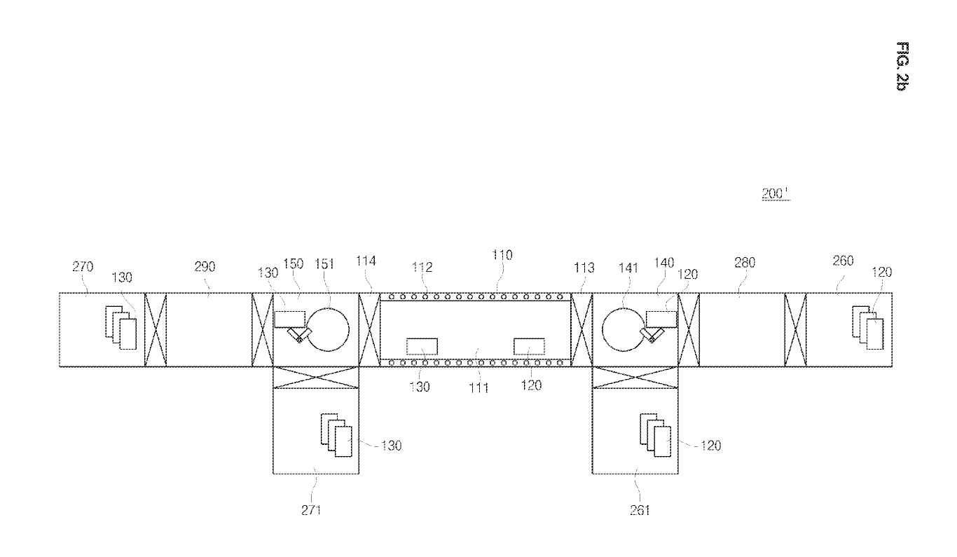

FIG. 2a shows a sublimation purification apparatus 200 according to a second embodiment of the present invention. In the second embodiment of the present invention, a transfer chamber 140 is connected to one end of a process chamber 110 via a gate 113, and a preheating chamber 280 is connected to the transfer chamber 140 via the other gate of the transfer chamber 140. A source material storing means 260 is connected to the preheating chamber 280 via a gate of the preheating chamber 280. The process chamber 110, the transfer chamber 140, the source material storing means 260, and the preheating chamber 280 may be separated from one another as necessary in the process.

In the source material storing means 260, one or more source material containers 120 containing source materials are stacked. Alternatively, the source material storing means 260 may further comprise a vacuum pump or a valve (not shown) connected to the source material storing means 260. When the gate between the source material storing means 260 and the preheating chamber 280 is open, one of the plurality of source material containers 120 are transferred from the source material storing means 260 into the preheating chamber 280. In this case, an arm of a robot 141 of the transfer chamber 140 may have a sufficient length for passing through the two gates of the preheating chamber 280, and the arm may transfer the source material containers 120 from the source material storing means 260 into the preheating chamber 280. Alternatively, other units (not shown) that are the same or similar to the transfer chamber 140 and the robot 141 may be further provided between the source material storing means 260 and the preheating chamber 280, and thus the source material containers 120 may be transferred by the units. Then, as described in the first embodiment, a preheating process of the source material container 120 containing the source materials is performed in the preheating chamber 280.

When a previous purification process is completed in the process chamber 110, the source material storing means 260 is displaced and connected to the transfer chamber 140, and the robot 141 transfers the empty source material container 120 after the purification process to the transfer chamber 140 and then transfers the source material storing means 260, and stacks the empty source material container 120 in the source material storing means 260. At this time, the preheating process may be simultaneously performed in the preheating chamber 280.

When the preheating process is completed, the robot 141 transfers the source material container 120 containing the preheated source materials from the preheating chamber 280 into the transfer chamber 140. When the gate of the process chamber 110 is open, the robot 141 loads the source material container 120 containing the source materials into the process chamber 110 again, and the purification process is performed in the process chamber 110.

Referring to FIG. 2a again, in the second embodiment of the present invention, a transfer chamber 150 is connected to the end of the process chamber 110 through a gate 114. A cooling chamber 290 is connected to the transfer chamber 150 via a gate of the transfer chamber 150, and a purified material storing means 270 is connected to the cooling chamber 290 via a gate of the cooling chamber 290. The process chamber 110, the transfer chamber 150, the purified material storing means 270, and the cooling chamber 290 may be separated from one another as necessary in the process.

One or more empty purified material collectors 130 containing purified materials are stacked in the purified material storing means 270. Alternatively, the purified material storing means 270 may further comprise a vacuum pump or a valve (not shown) connected to the purified material storing means 270. In order to transfer the empty purified material collector 130 into the process chamber 110 before the purification process of the process chamber 110, the purified material storing means 270, which was connected to the cooling chamber 290, is displaced to the transfer chamber 150. When the gate between the transfer chamber 150 and the purified material storing means 270 is open, the robot 151 transfers one of the plurality of empty purified material collectors 130 from the purified material storing means 270 to the transfer chamber 150. When the gate of the process chamber 110 is open, the robot 151 transfers the purified material collector 130 containing purified materials into the process chamber 110.

When the purification process is completed in the process chamber 110, the gate 114 of the process chamber 110 is open again, and the robot 151 unloads the purified material collector 130 containing purified materials into the transfer chamber 150. When the gate connecting the transfer chamber 150 and the cooling chamber 290 is open, the robot 151 transfers the purified material collector 130 to the cooling chamber 290. The gate of the cooling chamber 290 is closed, and the cooling chamber 290 cools the purified materials contained in the purified material collector 130.

In addition, the robot 151 transfers the empty purified material collector 130 to be used for the next purification process from the purified material storing means 270 to the transfer chamber 150, and transfers the empty purified material collector 130 into the process chamber 110, and then the next purification process is performed. At this time, the cooling process may be simultaneously performed in the cooling chamber 290.

When the cooling process is completed in the cooling chamber 290, the purified material storing means 270 is displaced and connected to the cooling chamber 290, as shown in FIG. 2a. When the gate between the cooling chamber 290 and the purified material storing means 270 is open, the purified material collector 130 containing purified materials is unloaded from the cooling chamber 290 to the purified material storing means 270. In this case, an arm of a robot 151 of the transfer chamber 150 may have a sufficient length for passing through the two gates of the cooling chamber 290, and the arm may transfer the purified material collector 130 from the cooling chamber 290 to the purified material storing means 270. Alternatively, other units (not shown) that are the same or similar to the transfer chamber 150 and the robot 151 may be further provided between the purified material storing means 270 and the cooling chamber 290, and thus the purified material collector 130 may be transferred by the units.

FIG. 2b shows a sublimation purification apparatus 200′ which partially modifies the apparatus according to the second embodiment shown in FIG. 2a, The sublimation purification apparatus 200′ of FIG. 2b further comprises an independent storing means 261 storing the empty source material container 120 after the purification process. In FIG. 2a, so that both the source material containers 120 containing the source materials before the purification process and the empty source material containers 120 after the purification process are stored in the source material storing means 260, the source material storing means 260 is displaced to either the gate of the transfer chamber 140 or the gate of the preheating chamber 280, and is selectively connected to the transfer chamber 140 and the preheating chamber 280 according to the corresponding process. In the sublimation purification apparatus 200′ shown in FIG. 2b, the source material storing means 260 is connected to the preheating chamber 280. The source material container 120 containing the source materials is loaded from the source material storing means 260 into the preheating chamber 280, and the empty source material containers 120 after the purification process is stored in the independent storing means 261 which is connected to the transfer chamber 140.

Referring to FIG. 2b again, the sublimation purification apparatus 200′ of the present invention further comprises an independent storing means 271 in which empty the purified material collectors 130 to be used for the purification process are stored. In the sublimation purification apparatus 200 of FIG. 2a, so that both the empty purified material collectors 130 to be used for the purification process and the purified material collectors 130 containing purified materials after the purification process are stored in the purified material storing means 270, the purified material storing means 270 is displaced to either the gate of the transfer chamber 150 or the gate of the cooling chamber 290, and is selectively connected to the transfer chamber 150 and cooling chamber 290 according to the corresponding process. In the sublimation purification apparatus 200′ shown in FIG. 2b, the purified material storing means 270 is connected to the cooling chamber 290, and the cooled purified material collector 130 containing purified materials is unloaded from the cooling chamber 290 into the purified material storing means 270 and is stored in the purified material storing means 270. The empty purified material collector 130 to be used for the purification process is stored in the independent storing means 271 connected to the transfer chamber 150, and then is transferred into the transfer chamber 150 for the purification process.

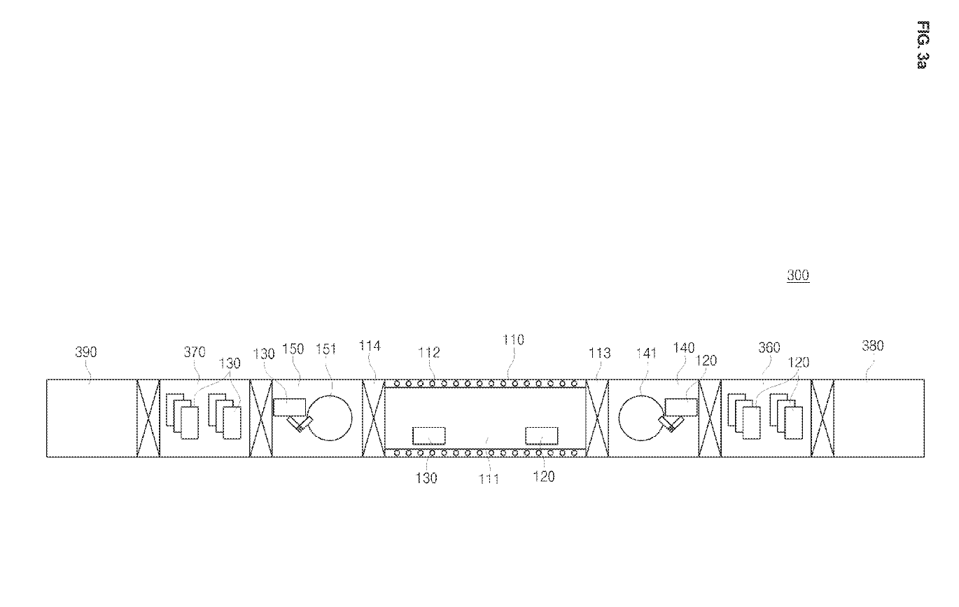

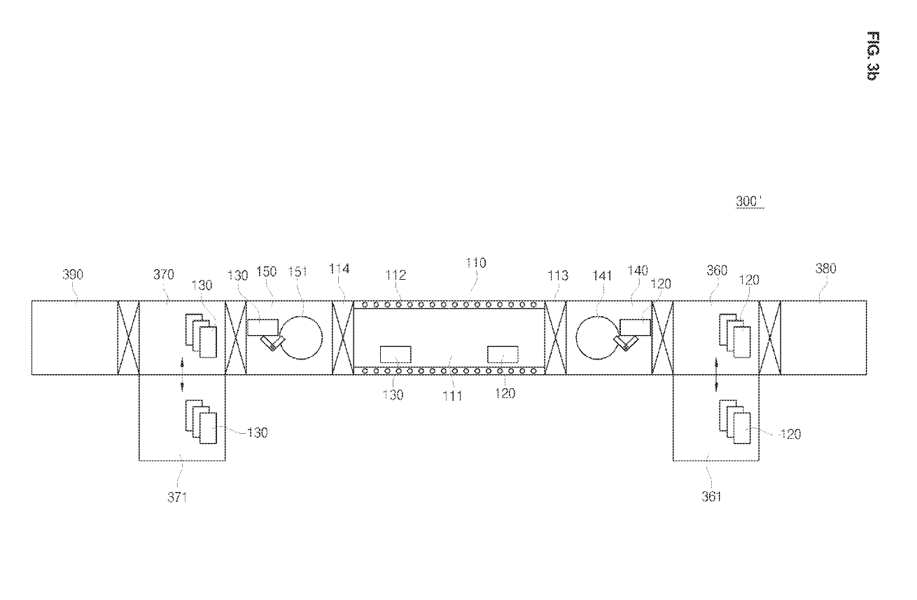

FIG. 3a shows a sublimation purification apparatus 300 according to a third embodiment of the present invention. In the third embodiment of the present invention, a transfer chamber 140 is connected to one end of a process chamber 110 via a gate 113, and a source material storing means 360 is connected to the transfer chamber 140 via the other gate of the transfer chamber 140. A preheating chamber 380 is connected to the source material storing means 360 via a gate of the source material storing means 360. The process chamber 110, the transfer chamber 140, the source material storing means 360, and the preheating chamber 380 may be separated from one another as necessary in the process.

The source material containers 120 containing source materials before the purification process and the empty source material containers 120 after the purification process are stored in the source material storing means 360. Alternatively, the source material storing means 360 may further comprise a vacuum pump or a valve (not shown) connected to the source material storing means 360.

One of the plurality of source material containers 120 is transferred from the source material storing means 360 into the preheating chamber 380 by a robot 141, and a preheating process for the source material containers 120 containing the source materials is performed in the preheating chamber 380. When the preheating process is completed, the robot 141 transfers the source material container 120 containing the preheated source materials from the preheating chamber 380 to the transfer chamber 140, through the source material storing means 360, and then loads the source material container 120 into the process chamber 110 again. The purification process is performed in the process chamber 110.

When the purification process is completed in the process chamber 110, the robot 141 transfers the empty source material container 120 after the purification process to the transfer chamber 140, and then transfers the empty source material container 120 to the source material storing means 360 and stacks the empty source material container 120 in the source material storing means 360. At this time, the next preheating process may be simultaneously performed in the preheating chamber 380.

Here, it has been described that the source material container 120 is transferred between the source material storing means 360 and the preheating chamber 380 by the robot 141. Alternatively, other units (not shown) that are the same or similar to the transfer chamber 140 and the robot 141 may be further provided between the source material storing means 360 and the preheating chamber 380, and thus the source material container 120 may be transferred by the transfer unit.

Referring to FIG. 3a again, in the third embodiment of the present invention, a transfer chamber 150 is connected to the end of the process chamber 110 via a gate 114. A purified material storing means 370 is connected to the transfer chamber 150 via the other gate of the transfer chamber 150, and a cooling chamber 390 is connected to the purified material storing means 370 via a gate of the purified material storing means 370. The process chamber 110, the transfer chamber 150, the purified material storing means 370, and the cooling chamber 390 may be separated from one another as necessary in the process.

An empty purified material collector 130 to be used for a purification process and a purified material collector 130 containing the purified materials after the purification process are stored in the purified material storing means 370. Alternatively, the purified material storing means 370 may further comprise a vacuum pump or a valve (not shown) connected to the purified material storing means 370.

When the purification process is completed in the process chamber 110, the robot 151 unloads the purified material collector 130 containing purified materials from the process chamber 110 to the transfer chamber 150, and then transfers the purified material collector 130 from the transfer chamber 150 to the cooling chamber 390, through the purified material storing means 370. The cooling chamber 390 cools the purified materials contained in the purified material collector 130. When the cooling process is completed in the cooling chamber 390, the robot 151 unloads the cooled purified material collector 130 containing purified materials from the cooling chamber 390 into the purified material storing means 370, and then the purified material collector 130 is stored in the purified material storing means 370.

In addition, the robot 151 transfers the empty purified material collector 130 to be used for the next purification process from the purified material storing means 370 to the transfer chamber 150, and transfers the purified material collector 130 into the process chamber 110, and then the next purification process is performed. At this time, the cooling process may be performed in the cooling chamber 390.

Here, it has been described that the purified material collector 130 is transferred between the purified material storing means 370 and the cooling chamber 390 by the robot 151 installed in the transfer chamber 150. Alternatively, other units (not shown) that are the same or similar to the transfer chamber 150 and the robot 151 may be further provided between the purified material storing means 370 and the cooling chamber 390.

FIG. 3b shows a sublimation purification apparatus 300′ which partially modifies the apparatus according to the third embodiment shown in FIG. 3a. In the sublimation purification apparatus 300′ of FIG. 3b, the source material containers 120 containing the source materials are stored in the source material storing means 360, and the empty source material containers 120 after the purification process are stored in an independent storing means 361. The source material storing means 360 and the independent storing means 361 may be displaced in a leftward/rightward direction, in an upward/downward direction, or in other various directions, so as to be connected to the transfer chamber 140 or the preheating chamber 180, according to the corresponding process.

Referring to FIG. 3b again, in the sublimation purification apparatus 300′, the purified material collectors 130 containing purified materials are stored in the purified material storing means 370, and the empty purified material collectors 130 to be used for the purification process are stored in the independent storing means 371. The purified material storing means 370 and the independent storing means 371 may be displaced in a leftward/rightward direction, in an upward/downward direction, or in other various directions, so as to be connected to the transfer chamber 150 or the cooling chamber 160 according to the corresponding process.

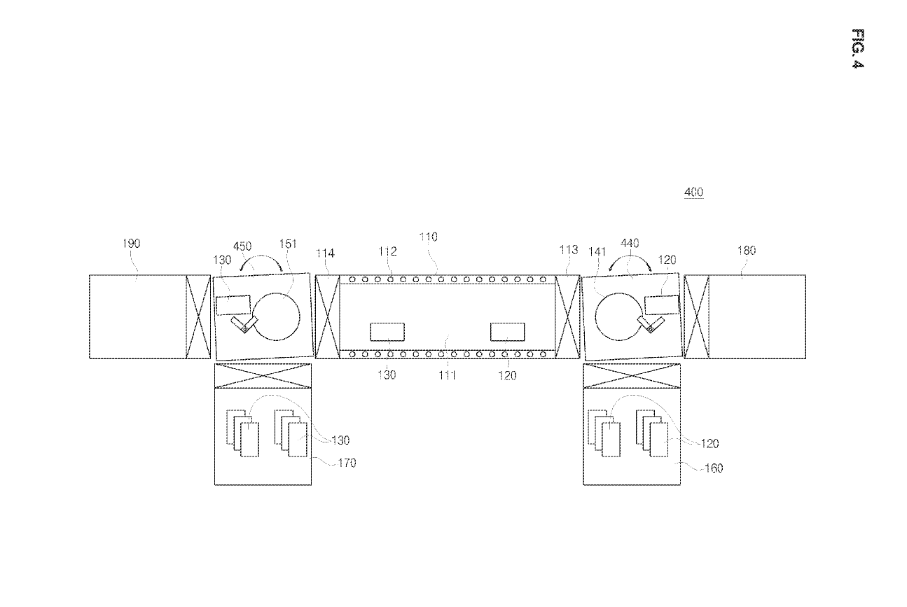

FIG. 4 shows a sublimation purification apparatus according to a fourth embodiment of the present invention, which partially modifies the apparatus according to the apparatus 100 of FIG. 1a. The transfer chamber 140 of FIG. 1 has the plurality of gates. However, in the fourth embodiment, a transfer chamber 440 may have one gate, and the transfer chamber 440 is rotated and/or displaced, and connected to the process chamber 110, the source material storing means 160, or the preheating chamber 180. Then, the corresponding process is performed. Likewise, a transfer chamber 450 used for an unloading process may have one gate. The transfer chamber 450 is rotated and/or displaced, and connected to the process chamber 110, the purified material storing means 170, or the cooling chamber 190. Then, the corresponding process is performed.

As described above, the embodiments of the present invention use the robots 141 and 151 as means for transferring the source material containers 120 and the purified material collectors 130. Alternatively, the robots 141 and 151 may be conveyor belts controlled by a remote controller, or any other automatic transporting means.

So far, the present invention has been described with respect to the exemplary embodiments disclosed above. It can be understood by a person having ordinary skill in the art that these embodiments may be implemented in modified forms without departing from the essential characteristics of the present invention. Therefore, the disclosed embodiments should be considered to explain the present invention, but not to limit the present invention. The scope of the present invention is determined by the appended claims rather than the above descriptions, and all differences within a range equivalent thereto should be construed as being comprised in the present invention.

### DESCRIPTION OF THE REFERENCE NUMERALS

100: sublimation purification apparatus, 110: process chamber, 120: source material container, 130: purified material collector, 141: robot, 151: robot, 160: source material storing means, 170: purified material storing means, 180: preheating chamber, 190: cooling chamber

1. A sublimation purification apparatus comprising:
a first robot having an arm for loading a container containing a source material into a process chamber;
the process chamber for performing a sublimation purification process to obtain a purified material from the source material, wherein the container containing the source material and a collector collecting a purified material are located at predetermined locations within the process chamber; and
a second robot having an arm for unloading the collector containing the purified material from the process chamber.

2. The sublimation purification apparatus according to claim 1, further comprising a preheating chamber for a preheating process of the source material contained in the container, wherein the preheated source material is loaded into the process chamber by the first robot.

3. The sublimation purification apparatus according to claim 1, further comprising a cooling chamber for a cooling process of the purified material contained in the collector, wherein the purified material is loaded into the cooling chamber by the second robot.

4. A sublimation purification method comprising:
preheating a source material contained in a container in a preheating chamber;
loading the container containing the preheated source material into a process chamber by using an arm of a first robot and locating the container at a predetermined location;
performing a sublimation purification process to obtain purified material from the source material in the process chamber, wherein the purified material is collected in a collector located at a predetermined location;
unloading the collector containing the purified material from the process chamber by using an arm of a second robot; and
initiating another preheating process in the preheating chamber contemporaneously with the sublimation purification process.

5. The sublimation purification method according to clam 4, further comprising loading the unloaded collector containing the purified material to a cooling chamber by the second robot for cooling process of the purified material,
wherein the cooling process is performed in contemporaneous with another sublimation purification process in the process chamber.
